(19) United States
(12) Patent Application Publication
(10) Pub. No.: US 2024/0383078 A1
(43) Pub. Date: Nov. 21, 2024

(54) CHIP BONDING COMPOSITION FOR POWER SEMICONDUCTOR PACKAGE

(71) Applicant: TERAON CO., LTD, Seongnam-si, Gyeonggi-do (KR)

(72) Inventors: Yoon-Jin KIM, Seongnam-si, Gyeonggi-do (KR); Hyun-Jun KIM, Seongnam-si, Gyeonggi-do (KR); Young-Hun KIM, Seongnam-si, Gyeonggi-do (KR); Tae-Hee KIM, Seongnam-si, Gyeonggi-do (KR)

(73) Assignee: TERAON CO., LTD, Seongnam-si, Gyeonggi-do (KR)

(21) Appl. No.: 18/693,857

(22) PCT Filed: Sep. 15, 2022
(86) PCT No.: PCT/KR2022/013823

§ 371 Date: Mar. 20, 2024

(30) Foreign Application Priority Data
Sep. 29, 2021 (KR) 10-2021-0128530

(51) Int. Cl. B23K 35/02; B22F 1/103; B23K 35/30; B23K 35/365; B23K 101/40

(52) U.S. Cl. CPC B23K 35/025; B22F 1/103; B23K 35/3006; B23K 35/365; B22F 2301/255; B23K 2101/40

(57) ABSTRACT

Disclosed is a chip bonding composition for a power semiconductor package, which, by comprising an epoxy resin including glycidyl amine-based epoxy resin and bisphenol A type epoxy resin, a glycidyl ether-based diluent, and a polysilsesquioxane (PSQ) resin, has high thermal conductivity and adhesion, high heat dissipation characteristics, and low modulus characteristics. The chip bonding composition according to the present invention comprises: silver powder; an epoxy resin; a curing agent; a catalyst; a glycidyl ether-based diluent; and a PSQ resin.

### TECHNICAL FIELD

Embodiments relate to a chip bonding composition for power semiconductor packages with high thermal conductivity, adhesion, high heat dissipation, and low modulus.

### BACKGROUND ART

Recently, as the eco-friendly automobile and renewable energy markets have increased, the demand for high-output and high-efficiency power semiconductors has increased.

Accordingly, the need for wide band gap (WBG) compound semiconductors based on silicon carbide (sic), gallium nitride (GaN) or the like is increasing.

Power semiconductors improve energy efficiency and stably control changes in voltage in the process of transmitting and controlling power to provide stability and reliability of the system.

Among wide band gap (WBG) compounds, SiC has an about 10-fold higher breakdown field strength and an about 3-fold higher band gap than Si.

SiC is capable of controlling p-type and n-type semiconductors required to manufacture devices within a wide range. Advantageously, Sic has a thermal conductivity of 4.9 W/mK which is about 3 times higher than 1.5 W/mK which is thermal conductivity of Si.

In addition, siC has a melting point of 300° C. or higher and thus operates stably even at a high operating temperature.

It is known that, when a conventional Si IGBT (insulated gate bipolar transistor) power semiconductor is changed to a SiC power semiconductor, the volume is reduced by about 50% or less and the energy efficiency is increased by about 85% or more.

Accordingly, it is expected that SiC power semiconductors will be essentially used instead of conventional Si IGBT power semiconductors in the field requiring high voltage, high current, and high power.

Power semiconductors are typically applied in the form of modules containing power semiconductors to products. A power semiconductor package or module has a configuration in which direct bonding copper (DBC), wherein copper is directly bonded, is disposed on top and bottom of a ceramic substrate. A power semiconductor package or module has a configuration in which a power semiconductor chip bonded by a solder is disposed on top of the DBC. A metal base plate is bonded to the bottom of the DBC by a solder.

A power semiconductor package using Sic in a power semiconductor chip has a much higher operating temperature than a conventional semiconductor package using Si therein. For this reason, there is a need for methods that are capable of increasing thermal conductivity within the package, improving resistance to thermal stress, and maximizing excellent physical properties of siC.

In this regard, the bonding material of the power semiconductor chip should basically have high adhesion, high heat dissipation, and durability against repeated thermal shock. In addition, the bonding material should not re-melt even at high operating temperatures and should be commercially fair and cost-competitive.

Compositions such as Ag—Pb and Sn—Ag—Cu (SAC) are mainly used as bonding materials for power semiconductor chips, but these bonding materials have several problems and are thus inapplicable to power semiconductor packages using SiC.

This is because compositions such as Ag—Pb and Sn—Ag—Cu (SAC) are remelted at around 180° C., thus causing defects such as cracks and fatigue failure and being unsuitable for use in high-pressure, high-current, high-temperature power semiconductors.

In addition, lead solder materials or SAC materials cause interfacial peeling, stress concentration, and permanent creep deformation in the thin film layer due to thermal fatigue as the power is repeatedly turned on and off. In addition, Cu/Sn/Cu transient liquid phase bonding (TLP) has a multilayer interface and thus often cracks, causing problems associated with reliability.

The process using bonding compositions includes soldering, eutectic bonding, pressure sintering, and non-pressure sintering.

Metal sintering such as soldering provides a solid film from the bonding material. In addition, metal sintering is known to be the best alternative because it exhibits high adhesive strength, high thermal conductivity of about 150 to 300 W/mK, and high melting point.

Pressure sintering allows sintering bonding at a pressure of about 30 MPa and at 200 to 250° C. for about 5 minutes. However, pressure sintering is practically inapplicable to mass production due to severe chip damage by pressing and is limitedly used only for very expensive power modules in the expanded contact area of the metal powder.

Pressure-free sintering is the most ideal method, but has limitations in that it takes more than 200 minutes for sintering and lacks mass production due to the high process temperature.

Pressure-free sintering using copper is disadvantageously inapplicable due to the difficulty of using an inert gas atmosphere in the bonding process and the problem of oxidation during use.

Conventional chip bonding compositions applicable to sintering are advantageous in ensuring high heat dissipation properties. However, the conventional chip bonding compositions have a problem in that delamination between the chip and the bonding material, or the lead frame and the substrate frequently occurs after the temperature cycling test due to the high modulus.

Generally, when a silver powder in the chip bonding material is melted and sintered, the chip bonding material shrinks and increases in the modulus thereof. When the chip bonding material is cooled and heated repeatedly from a low temperature of −40° C. or lower to a high temperature of 125° C. or higher, the chip bonding material bends upward and downward, disadvantageously causing cracks and peeling. Accordingly, the chip bonding material has a conventional limitation in applying bonding materials to mid-to large-sized chips with a size of 4×4 mm² or larger.

Therefore, there is a need for a chip bonding composition to replace conventional chip bonding materials that has high thermal conductivity, heat resistance, high heat dissipation characteristics and low modulus, and can be applied to mid-to large-sized chips.

### DISCLOSURE

### Technical Problem

One embodiment provides a chip bonding composition for power semiconductor packages with excellent thermal conductivity and adhesion.

Another embodiment provides a chip bonding composition for power semiconductor packages with excellent heat dissipation characteristics and low modulus characteristics.

Another embodiment provides a chip bonding composition for power semiconductor packages applicable to high-power mid-to large-sized SiC and GaN chips.

Another embodiment provides a chip bonding composition for power semiconductor packages applicable to pressure-free sintering that can dramatically shorten process time and temperature.

The objects of the present disclosure are not limited to the objects mentioned above and other objects and advantages of the present disclosure not mentioned herein will be understood by the following description and will be more clearly understood by the examples of the present disclosure. In addition, it will be obvious that the objects and advantages of the present disclosure can be implemented by the means and combinations thereof defined in claims.

### Technical Solution

In an embodiment, a chip bonding composition contains a silver powder, an epoxy resin, a curing agent, a catalyst, a glycidyl ether-based diluent and a polysilsesquioxane (PSQ) resin.

The silver powder may provide high thermal conductivity.

The epoxy resin may include a resin that is a mixture of a glycidyl amine-based epoxy resin and a bisphenol A epoxy resin, to provide low modulus.

The chip bonding composition may contain 1 to 7 parts by weight of the epoxy resin, 0.01 to 5 parts by weight of the catalyst, 0.2 to 3 parts by weight of the glycidyl ether-based diluent, and 1 to 6 parts by weight of the polysilsesquioxane (PSQ) resin, based on 100 parts by weight of the silver powder, and a mixing ratio of the epoxy resin to the curing agent may be a weight ratio of 1:1 to 1:2.

### Advantageous Effects

The chip bonding composition for power semiconductor packages according to the present disclosure exhibits excellent thermal conductivity, adhesion and heat dissipation, and low modulus.

In addition, the chip bonding composition for power semiconductor packages to the present disclosure reduces mechanical stress applied to the power semiconductor package by thermal shock, thereby providing excellent durability and reliability even at high operating temperatures of power semiconductor chips.

In addition, the chip bonding composition for power semiconductor packages according to the present disclosure advantageously increases the operating temperature of SiC and GaN semiconductor packages because it does not re-melt even at temperatures of 300° C. or higher after completion of heat treatment (reflow) in spite of low operating temperatures.

In addition, the chip bonding composition for power semiconductor packages of the present disclosure exhibits high adhesive strength regardless of the type of metal present at the interface between the power semiconductor chip and the lead frame or between the power semiconductor chip and the substrate, such as DBC (direct bonding copper).

The chip bonding composition for power semiconductor packages according to the present disclosure is applicable to high-power mid-to large-sized SiC and GaN chips.

The chip bonding composition for power semiconductor packages according to the present disclosure is applicable to pressure-free sintering that can dramatically shorten process time and temperature.

Detailed effects of the present disclosure in addition to the effects described above will be described below along with details for implementing the invention.

### BRIEF DESCRIPTION OF DRAWINGS

FIG. 1 shows patterning a chip bonding composition of Example 1 of the present disclosure on a DBC substrate using a dispenser.

FIG. 2 shows the result of test on workability over time of the chip bonding composition of Example 1 according to the present disclosure.

FIG. 3 is a cross-sectional image showing the chip bonding composition of Example 1 according to the present disclosure applied and sintered between a substrate and a SiC chip.

FIG. 4 shows DST (surface) after the adhesion strength test depending on the type of metal plated on the DBC substrate, and SEM image and porosity of the sintered composition.

### BEST MODE

The objects, features and advantages described above will be described in detail with reference to the annexed drawings. Those skilled in the art of the present disclosure will be able to easily implement the technical idea of the present disclosure. In the following description of the present disclosure, detailed descriptions of the prior art to which the present disclosure pertains will be omitted when they may obscure the subject matter of the present disclosure. Hereinafter, preferred embodiments according to the present disclosure will be described in detail with reference to the attached drawings. Like numbers refer to like elements throughout the description of the drawings.

It should be understood that when an element is referred to as being a “top” (or a “bottom”) or “on” (or “under”) another element, it may directly contact the upper surface (or lower surface) of the other element or an intervening element may also be present therebetween.

In addition, it should be understood that, when one element is referred to as being “bound,” “linked” or “connected” to another element, the elements may be directly bound or connected to each other, or may be “bound,” “linked” or “connected” to each other via the other element.

Hereinafter, the chip bonding composition for power semiconductor packages according to some embodiments of the present disclosure will be described.

The chip bonding composition for power semiconductor packages according to the present disclosure is a material that can replace conventional solder pastes such as Sn—Ag—Cu (SAC) and has high thermal conductivity and adhesion as well as high heat dissipation and low modulus.

Advantageously, the chip bonding composition is applicable to SiC- and GaN-based power semiconductor packages, semiconductor packages such as modules, communication modules, CPUs and GPUs, high-power LED packages, and the like, and is suitable for mid-to large-sized chips.

The chip bonding composition for power semiconductor packages according to the present disclosure contains a silver powder as a main ingredient and may contain a silver powder, an epoxy resin, a curing agent, a catalyst, a glycidyl ether-based diluent, and a polysilsesquioxane (PSQ) resin.

The silver powder constituting the chip bonding composition for power semiconductor packages according to the present disclosure serves to provide high thermal conductivity. The chip bonding composition preferably contains a large amount of silver powder.

The silver powder has a flake or plate shape, not a spherical shape.

The thickness of the silver powder provided in the form of the flake or plate may be 0.1 to 200 nm, specifically 1 to 150 nm, 1 to 100 nm, and more specifically 10 to 100 nm.

The silver powder having a nano-scale thickness is advantageously sintered at low temperatures when combined with an organic material, which will be described later.

In addition to the large amount of silver powder, the chip bonding composition preferably contains an epoxy resin mixture of a glycidyl amine-based epoxy resin and a bisphenol A epoxy resin in order to secure sufficient fluidity.

Epoxy resins were mainly used as chip bonding compositions in the conventional semiconductor package field. In particular, bisphenol A type epoxy resin has a large free volume and thus a high coefficient of thermal expansion of 55 to 75 ppm/° C. Although bisphenol A type epoxy resins are highly impregnated with a thermally conductive powder, there is a limitation to lowering the coefficient of thermal expansion of bisphenol A type epoxy resins. In addition, there is a limit to impregnating bisphenol A epoxy resins with a large amount of thermally conductive powder due to the high viscosity of the bisphenol A epoxy resin.

The coefficient of thermal expansion is a considerably essential requirement to secure the reliability of power semiconductor packages. When the coefficient of thermal expansion of one of the power semiconductor package components is greatly different from that of another component, or when the coefficient of thermal expansion of one component is very high, the component having a high coefficient of thermal expansion or the component having a great difference in coefficient of thermal expansion may cause fatal problems such as cracks during thermal cycling.

In addition, when the silver powder in the bonding material melts, necking or sintering occurs, thus increasing the modulus and causing problems such as cracking and peeling due to vertical bending. Therefore, there is a problem in applying bonding materials to mid- to large-sized chips.

In order to solve these problems, a mixed epoxy resin containing a glycidyl amine-based epoxy resin and a bisphenol A epoxy resin was used in the present disclosure.

The chip bonding composition exhibits sufficient fluidity despite containing a large amount of silver powder because it contains a combination of a glycidyl amine-based epoxy resin and a bisphenol A epoxy resin and thus is present as a liquid with low viscosity.

In particular, an epoxy resin mixture of a glycidyl amine-based epoxy resin and a bisphenol A epoxy resin imparts low modulus and relieves mechanical stress applied to the power semiconductor packages due to thermal shock. Accordingly, a chip bonding composition containing an epoxy resin exhibits sufficient durability and reliability even at high operating temperatures of power semiconductor chips.

The glycidyl amine-based epoxy resin contains at least one nitrogen atom and lone pairs of electrons. The glycidyl amine-based epoxy resin has lone pairs of electrons on oxygen as well as on nitrogen.

The glycidyl amine-based epoxy resin includes at least one of triglycidyl p-aminophenol (TGPAP), tetraglycidyl diaminodiphenylmethane (TGDDM), triglycidyl m-aminophenol (TGMAP), tetraglycidyl diaminodiphenylsulfone (TGDDS), diglycidyl aniline, or diglycidyl-o-toluidine.

The chip bonding composition preferably contains the mixed epoxy resin in an amount of 1.0 to 7.0 parts by weight, and more preferably 1.9 to 6.7 parts by weight, based on 100 parts by weight of the silver powder.

The glycidyl amine-based epoxy resin may be contained in an amount of 0.1 to 6.0 parts by weight and the bisphenol A epoxy resin may be contained in an amount of 0.1 to 6.0 parts by weight. Preferably, the glycidyl amine-based epoxy resin may be contained in an amount of 1.0 to 3.0 parts by weight and the bisphenol A type epoxy resin may be contained in an amount of 0.2 to 5.0 parts by weight.

The chip bonding composition contains 1 to 7 parts by weight of the mixed epoxy resin, thereby exhibiting high thermal conductivity and allowing the silver powder to be sintered smoothly.

When the content of the mixed epoxy resin is less than 1 part by weight, it may be insufficient to relieve mechanical stress applied to the power semiconductor package and to ensure durability and reliability of the power semiconductor package.

On the other hand, when the content of the mixed epoxy resin exceeds 7 parts by weight, as the resin content increases, the resin acts as an obstacle that prevents sintering of the silver powder, thus causing the problem of the deteriorated heat dissipation.

The chip bonding composition contains a curing agent in addition to the combination of two types of epoxy resins.

The curing agent has effects of slowing down the curing speed and increasing work stability. In addition, the curing agent ensures high hardening density and forms a continuous welding phase of silver powder.

Specifically, curing may be performed at a low temperature of 250° C. or lower due to the exothermic reaction heat generated by the curing reaction and externally applied heat. At the same time, welding between silver powder particles may effectively proceed. Accordingly, high curing density and the continuous welding phase of silver powder can be formed, which has the effect of increasing thermal conductivity. In addition, the process time and temperature can be dramatically shortened, which has the advantage of being suitable for pressure-free sintering.

The curing agent may include an acid anhydride-based curing agent.

The acid anhydride-based curing agent may include at least one of nadic maleic anhydride, dodecyl succinic anhydride, maleic anhydride, succinic anhydride, methyltetrahydrophthalic anhydride, hexahydrophthalic anhydride (HHPA), tetrahydrophthalic anhydride, pyromellitic dianhydride, cyclohexanedicarbonyl anhydride, methyltetrahydrophthalic anhydride (MeTHPA), methylhexahydrophthalic anhydride (MeHHPA), nadic methyl anhydride (NMA), hydrolyzed methyl nadic anhydride, phthalic anhydride, or nadic anhydride.

The mixing ratio of the mixed epoxy resin and the curing agent is preferably a weight ratio of 1:1 to 1:2. For example, the mixing ratio may be a weight ratio of 1:1 or a weight ratio of 1:2.4.

In other words, when the mixed epoxy resin is contained in an amount of 1.0 to 7.0 parts by weight, the curing agent may be contained in an amount of 2.0 to 8.0 parts by weight, and preferably, 3.0 to 7.0 parts by weight.

When the mixing ratio of the mixed epoxy resin and the curing agent does not fall within the weight ratio range of 1:1 to 1:2, the exothermic reaction due to the curing reaction is not performed normally, resulting in insufficient curing at low temperatures and insufficient welding between the silver powder particles.

The chip bonding composition contains a catalyst to facilitate the curing reaction between the epoxy resin containing a nitrogen atom and a lone pair of electrons and the acid anhydride-based curing agent.

The catalyst may include an imidazole-based catalyst.

The imidazole-based catalyst may include at least one of 2-methylimidazole (2MZ), 2-undecylimidazole (C11-Z), 2-heptadecylimidazole (C17Z), 1,2-dimethylimidazole (1.2DMZ), 2-ethyl-4-methylimidazole (2E4MZ), 2-phenylimidazole (2PZ), 2-phenyl-4-methylimidazole (2P4MZ), 1-benzyl-2-methylimidazole (1B2MZ), 1-benzyl-2-phenylimidazole (1B2 PZ), 1-cyanoethyl-2-methylimidazole (2MZ-CN), 1-cyanoethyl-2-ethyl-4-methylimidazole (2E4MZ-CN), 1-cyanoethyl-2-undecylimidazole (C11Z-CN), 1-cyanoethyl-2-phenylimidazolium trimellitate (2PZCNS-PW), 2,4-diamino-6-[2′-methylimidazolyl-(1′)]-ethyl-s-triazine (2MZ-A), 2, 4-diamino-6-[2′-undecylimidazolyl-(1′)]-ethyl-s-triazine (C11Z-A), 2, 4-diamino-6-[2′-ethyl-4′-methylimidazolyl-(1′)]-ethyl-s-triazine (2E4MZ-A), 2,4-diamino-6-[2′-methylimidazolyl-(1′)]-ethyl-s-triazine isocyanuric acid adduct (2MA-OK), 2-phenyl-4, 5-dihydroxymethylimidazole (2PHZ-PW), or 2-phenyl-4-methyl-5-hydroxymethylimidazole (2P4MHZ-PW).

The chip bonding composition preferably contains the catalyst in an amount of 0.01 to 5 parts by weight, more preferably 0.01 to 2.0 parts by weight, and even more preferably 0.05 to 1.0 parts by weight, based on 100 parts by weight of the silver powder.

When the content of the catalyst satisfies the range of 0.01 to 5 parts by weight, the catalyst can activate the curing agent without delaying the curing reaction time.

When an imidazole catalyst is added to the chip bonding composition, it primarily induces esterification between the epoxy resin and the curing agent through activation of the acid anhydride curing agent.

In addition, curing occurs competitively through esterification and etherification (ROR') by the hydroxyl groups of the epoxy resin and homopolymerization of the remaining epoxy.

As the content of imidazole catalyst increased, the esterification peaks gradually shifted to lower temperatures. The etherification peaks were observed at an almost constant temperature regardless of the catalyst content.

In addition, the reaction heat (total heat) generated during the curing reaction decreases as the catalyst content increases. This means that the conversion rate decreases as the catalyst content increases.

Taking into consideration the fact that the heat of reaction is preferably as high as possible because the chip bonding composition according to the present disclosure uses the heat generated by reaction between the epoxy resin and the curing agent, and external heat, the catalyst content is preferably 5 parts by weight or less, and more preferably 2 parts by weight or less.

The chip bonding composition contains a glycidyl ether-based diluent to increase flexibility after curing.

The glycidyl ether-based diluent is inserted between the main chains of the epoxy cured material through a chemical reaction to provide the effect of loosening the overall three-dimensional network structure of the composition. In other words, the glycidyl ether-based diluent is distributed between the three-dimensional network structures through reaction with the epoxy main chain, thereby increasing the flexibility of the chip bonding composition and lowering the modulus after curing.

In addition, the glycidyl ether-based diluent has a mono-or bi-functional group and lowers the viscosity of the chip bonding composition and thereby enable the silver powder to be added in a high amount.

The glycidyl ether-based diluent includes at least one of lauryl alcohol glycidyl ether (LGE), butyl glycidyl ether (BGE), 2-ethylhexyl glycidyl ether, allyl glycidyl ether (AGE), polypropylene glycol diglycidyl ether, 1,4-butanediol diglycidylether, neopentyl glycol diglycidyl ether, or 1,6-hexanediol diglycidyl ether.

The chip bonding composition preferably contains the glycidyl ether-based diluent in an amount of 0.2 to 3.0 parts by weight, and more preferably 0.4 to 3.0 parts by weight, based on 100 parts by weight of the silver powder.

By satisfying the content of the glycidyl ether-based diluent within the range of 0.2 to 3.0 parts by weight, excellent flexibility of the chip bonding composition can be secured.

On the other hand, when the content of the glycidyl ether-based diluent does not fall within the range of 0.2 to 3.0 parts by weight, the curing reaction speed is delayed and the glass transition temperature is lowered, and when the content of the glycidyl ether-based diluent is excessive, bubbles may be formed. As a result, disadvantageously, the adhesive strength of the chip bonding composition may be deteriorated.

The chip bonding composition contains a polysilsesquioxane (PSQ) resin to induce sintering of the silver powder even at low temperatures of 250° C. or lower.

The polysilsesquioxane resin is uniformly distributed within the matrix of the chip bonding composition to provide an effect of reducing modulus.

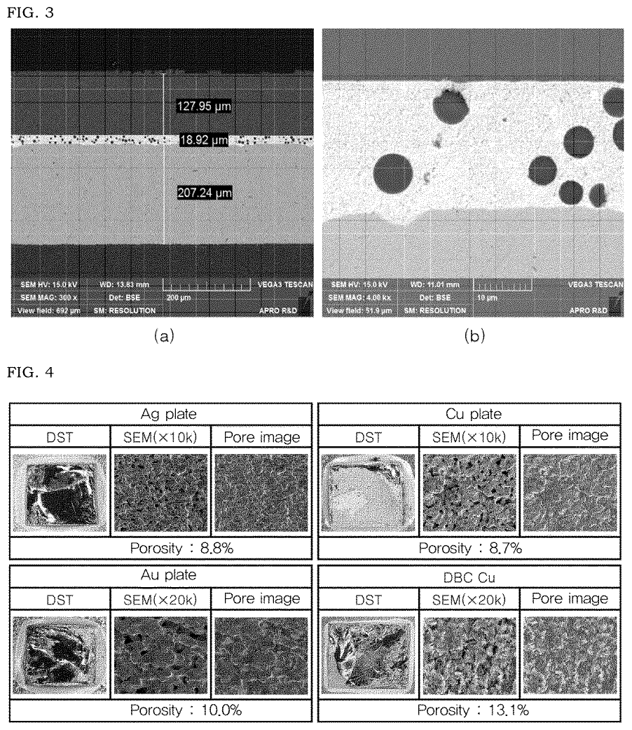

In addition, the polysilsesquioxane resin occupies a large volume fraction compared to the weight thereof and thus has the effect of reducing the distance between silver powder particles. As can be seen from FIG. 3(b), the black spherical polysilsesquioxane resin has the effect of reducing the volume of the matrix excluding the silver powder. The polysilsesquioxane resin does not react chemically or physically to curing and sintering, thus maintaining the original shape thereof even after curing and sintering.

Accordingly, the polysilsesquioxane resin has an effect of inducing sintering of silver powder even at low temperatures of 250° C. or lower without adding substances for inducing low-temperature sintering, such as metal complexes.

The polysilsesquioxane resin may include at least one of polypropylene silsesquioxane, polyphenyl silsesquioxane, or polymethylene silsesquioxane.

The chip bonding composition preferably contains the polysilsesquioxane (PSQ) resin in an amount of 1.0 to 6.0 parts by weight, and more preferably 1.0 to 5.8 parts by weight, based on 100 parts by weight of the silver powder.

When the content of the polysilsesquioxane resin is less than 1.0 parts by weight, there may be almost no effects of reducing modulus and improving sintering characteristics by the polysilsesquioxane resin.

On the other hand, when the content of the polysilsesquioxane resin is higher than 6.0 parts by weight, the dispersibility of the composition decreases and the viscosity increases, thus causing deterioration in the physical properties of the chip bonding composition and making it unsuitable for dispensing or screen printing.

As such, the chip bonding composition of the present disclosure contains a glycidyl ether-based diluent and a polysilsesquioxane (PSQ) resin, thereby exhibiting low modulus characteristics.

Accordingly, the chip bonding composition can secure stable adhesion in low-and high-temperature cycle tests on medium to large-sized power semiconductor packages.

Depending on process conditions, the chip bonding composition may further contain at least one of a butadiene-based dispersant, a phosphoric acid-based dispersant, or an ester-based dispersant.

The dispersant serves to maintain or improve the dispersibility of the chip bonding composition.

The chip bonding composition may further contain the dispersant in an amount of 0.1 to 3 parts by weight based on 100 parts by weight of the silver powder.

In addition, the chip bonding composition may further contain an organic solvent depending on process conditions.

The organic solvent includes at least one of diethylene glycol monobutyl ether (BC), diethylene glycol monoethyl ether acetate (CA), dipropylene glycol methyl ether (DPM) or dipropylene glycol n-butyl ether (DPNB).

The chip bonding composition may further contain the organic solvent in an amount of 0.01 to 100 parts by weight based on 100 parts by weight of the silver powder, but is not limited thereto.

The method of preparing the chip bonding composition for power semiconductor packages according to the present disclosure is as follows.

First, an epoxy resin including a glycidyl amine epoxy resin and a bisphenol A type epoxy resin, a curing agent, a dispersant, a diluent, and a PSQ resin were weighed and a homogeneous mixture was prepared using a planetary mixer or a rotating mixer.

Then, the silver powder was weighed, added to the resulting mixture, and stirred for about 30 minutes to 3hours using a planetary mixer.

Finally, a catalyst was added thereto, followed by stirring using a 3-roll mill provided with a chiller until the mixture was completely dispersed to prepare a chip bonding composition.

As described above, the chip bonding composition for power semiconductor packages according to the present disclosure exhibits high thermal conductivity, high adhesion, high heat dissipation, low modulus, and excellent durability against repeated thermal shock. In addition, the chip bonding composition does not re-melt even at high operating temperatures of 300° C. or higher, thereby increasing the operating temperature of the power semiconductor package and being commercially applicable.

In addition, the chip bonding composition exhibits high adhesive strength regardless of the type of metal present at the interface between the power semiconductor chip and the lead frame, or at the interface between the power semiconductor chip and the DBC.

Owing to this effect, the chip bonding composition can be applied to high-output, mid-to large-sized power semiconductor packages, and pressure-free sintering.

When the FT-IR spectrum before curing is analyzed using the chip bonding composition according to the present disclosure, characteristic peaks of the —C═O acid anhydride curing agent were observed at 1856.34 cm⁻¹ and 1777.82 cm⁻¹.

—C—O oxirane peaks were observed at 983.74 cm⁻¹, 912.55 cm⁻¹, and 897.87 cm⁻¹, and —C—O—C oxirane characteristic peaks were observed at 808.07 cm⁻¹.

A —C═O ester peak related to the dispersant was observed at 1721.02 cm⁻¹.

The —C═NH amine peak related to the catalyst was observed at 1634.48 cm⁻¹.

In addition, aromatic rings were observed at 1513,77 cm⁻¹, 1464.76 cm⁻¹, and 1406 cm⁻¹.

Specific examples of the chip bonding composition for power semiconductor packages are as follows.

### 1. Preparation of Chip Bonding Composition for Power Semiconductor Packages

First, an epoxy resin including a glycidyl amine epoxy resin and a bisphenol A type epoxy resin, a curing agent, a dispersant, a diluent, and a PSQ resin were weighed in parts by weight shown in Tables 1, 3 and 5 based on 100 parts by weight of the silver powder. Then, a homogeneous mixture was prepared using a planetary mixer or a rotating mixer.

Then, 100 parts by weight of a silver powder was weighed, added to the resulting mixture, and stirred for about 1 hour using a planetary mixer.

Finally, a catalyst was added thereto, followed by stirring using a 3-roll mill provided with a chiller until the mixture is completely dispersed to prepare a chip bonding composition.

### 2. Physical Property Test Method and Results Thereof

1) Specific resistance: the prepared chip bonding composition was printed in a size of 3 cm×3 cm using a screen printer. Then, the composition was cured at 170° C. for 30 minutes and at 220° C. for 60 minutes, the sheet resistance was measured with a 4-terminal probe using Loresta-GX, the thickness of the sample was measured and specific resistance was calculated.
2) Thermal conductivity: the prepared chip bonding composition was cast into a specimen with a diameter of 12.5 mm and a thickness of 2 mm, and then the specimen was coated with graphite to complete a sample for measuring thermal conductivity.

Thermal diffusivity was measured using LFA (laser flash analysis) and equipment calculated using the Equation of λ (thermal conductivity)=a (thermal diffusivity)×Cp (specific heat)×ρ (density).
3) Chip adhesion strength: the prepared chip bonding composition was dispensed on a silver-plated copper substrate and then a Sic chip with a size of 5 mm×5 mm was placed thereon. Then, the chip was subjected to heat treatment at 240° C. to prepare a sample for measurement.

Shear strength was measured at room temperature (25+1° C.) using a die shear tester.
4) Storage modulus: The prepared chip bonding composition was cast to prepare a sample for DMA measurement. The elastic modulus of the DAP bonding material was measured at room temperature and 200° C. using a dynamic mechanical analyzer (DMA). A static force of 110 mN and a dynamic force of 100 mN were applied to the sample at a frequency of 1 Hz and measured at a temperature increase rate of 5° C./min.
5) Thermal cycle test: the thermal cycle test of the package sample having a 4.5 mm×4 mm SiC chip attached thereto was measured under the test condition G in accordance with JEDEC.

The sample was collected after 1,000 cycles and X-ray CT, package resistance variation, adhesive strength, and the like thereof were tested to determine pass or fail.

| | Minimum | Maximum |
|---|---|---|
| Test conditions | temperature (° C.) | temperature (° C.) |
| G | −40 (+10, −10) | +125 (+15, −0) |

TABLE 1

| | | Exam- | Exam- | Exam- | Exam- | Exam- | Exam- | Exam- |
|---|---|---|---|---|---|---|---|---|
| Component | | ple 1 | ple 2 | ple 3 | ple 4 | ple 5 | ple 6 | ple 7 |
| Epoxy | Triglycidyl ρ- | 1.7 | 1.7 | 1.7 | | | | |
| resin | aminophenol (TGPAP) | | | | | | | |
| | Tetraglycidyl | | | | 2.3 | 2.0 | 2.1 | 2.1 |
| | diaminodiphenylmethane | | | | | | | |
| | (TGDDM) | | | | | | | |
| | Diglycidyl of aniline | | | | | | | |
| | Diglycidyl of toluidine | | | | | | | |
| | Bisphenol A epoxy | 1.9 | 5.0 | 0.2 | 1.9 | 1.8 | 1.9 | 1.9 |
| | Urethane modified epoxy | | | | | | | |
| Curing | Methyltetrahydrophthalic | 4.5 | 6.7 | 4.5 | 4.7 | 4.6 | 4.9 | 4.9 |
| agent | anhydride (MeTHPA) | | | | | | | |
| | Methylhexahydrophthalic | | | | | | | |
| | anhydride (MeHHPA) | | | | | | | |
| | Nadic methyl | | | | | | | |
| | anhydride (NMA) | | | | | | | |
| Catalyst | 2E4MZ | 0.06 | 0.06 | 0.06 | 0.06 | 0.05 | 0.06 | 0.06 |
| Silver powder | | 100 | 100 | 100 | 100 | 100 | 100 | 100 |
| PSQ | PMSQ | 2.2 | 4.6 | 2.2 | 4.7 | 1 | 4.7 | 5.8 |
| resin | | | | | | | | |
| Polybutadiene dispersant | | | | | 1.2 | | 1.2 | |
| PPGDE | Polypropylene glycol | | | 2.0 | 0.4 | | | |
| diluent | diglycidyl ether | | | | | | | |
| | BGE (Butyl | 2.0 | 2.0 | | 1.2 | 0.4 | 3.0 | 1.6 |
| | Glycidyl Ether) | | | | | | | |

TABLE 2

| | | Exam- | Exam- | Exam- | Exam- | Exam- | Exam- | Exam- |
|---|---|---|---|---|---|---|---|---|
| Property | Unit | ple 1 | ple 2 | ple 3 | ple 4 | ple 5 | ple 6 | ple 7 |
| Specific | ×10⁻⁶ Qcm | 5.67 | 6.58 | 4.68 | 6.78 | 4.12 | 7.22 | 6.81 |
| resistance | | | | | | | | |
| Thermal | W/mK | 152 | 154 | 168 | 148 | 178 | 157 | 138 |
| conductivity | | | | | | | | |
| Chip | kgf/mm² | 4.6 | 6.8 | 5.4 | 7.9 | 4.8 | 8.2 | 9.2 |
| adhesive | | | | | | | | |
| strength | | | | | | | | |
| Storage | GPa | 14.5 | 13.2 | 15.1 | 12.7 | 18.7 | 12.4 | 13.8 |
| modulus | | | | | | | | |
| at 25° C. | | | | | | | | |
| Storage | GPa | 4.8 | 3.6 | 4.9 | 3.2 | 6.8 | 3.1 | 3.8 |
| modulus | | | | | | | | |
| at 200° C. | | | | | | | | |
| Thermal | Pass | Pass | Pass | Pass | Pass | Pass | Pass | Pass |
| cycle test | | | | | | | | |
| (JEDECG | | | | | | | | |
| grade) | | | | | | | | |

The results of Examples 1 to 7 were analyzed. The results show that all the chip bonding compositions of Examples 1 to 7 have a resistivity of 1×10⁻⁶ to 1×10⁻⁶ Ωcm, a thermal conductivity of 100 to 200 W/mK, a chip adhesion strength of 4.0 to 10.0 kgf/mm², a storage modulus of 1 to 20 GPa at room temperature, and a storage modulus of 1 to 10 GPa at 200° C.

In particular, all the chip bonding compositions of Examples 1 to 7 have a storage modulus of 12 to 19 GPa at room temperature and a storage modulus of 3 to 7 GPa at 200° C.

It can be seen that, as the contents of the reactive glycidyl ether-based diluent and the PSQ resin increase, the storage modulus at room temperature and at 200° C. decreases.

Example 6 has high amounts of PSQ resin and reactive glycidyl ether-based diluent and exhibits the lowest storage modulus.

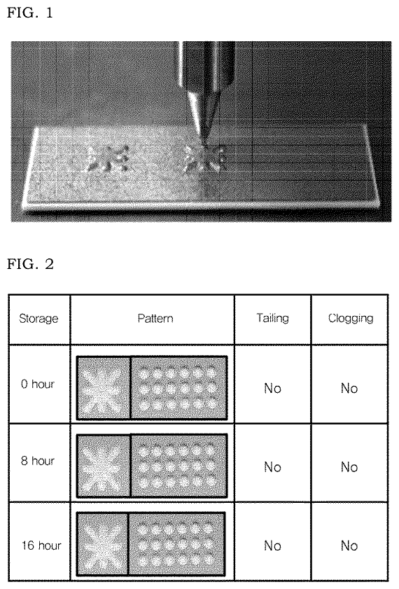

As shown in FIG. 1, the chip bonding composition of Example 1 was dispensed on the DBC substrate using a dispenser.

Changes were observed over time. The results show that stable patterns are formed without tailing or clogging for up to 16 hours, as shown in FIG. 2.

Here, tailing refers to a phenomenon in which when the chip bonding composition is patterned using a dispenser, tail-type defective patterns are formed on the surface of the droplet due to problems with rheology and surface tension. Clogging refers to a phenomenon in which a nozzle is blocked due to surface curing of the chip bonding composition located in the dispenser nozzle.

FIG. 3 is a cross-sectional image showing the chip bonding composition of Example 1 applied and sintered between a substrate and a SiC chip according to the present disclosure.

As can be seen from FIG. 3, the chip bonding composition of Example 1 was sintered under heat treatment conditions at 220° C. This shows that sintering is possible without using a silver complex compound for low-temperature sintering.

The silver powder used in Example 1 is not spherical but has a flake or plate shape, and has a diameter and thickness depending on the flake or plate shape.

The silver powder used in Example 1 has a large diameter (D50) of 4 μm or less and a small thickness of 100 nm or less.

When the diameter of the silver powder is large, sintering does not usually occur at low temperatures and thus sintering does not occur at 250° C.

Since the thickness of the silver powder used in Example 1 is 100 nm or less, the silver powder does not melt at a relatively low temperature. However, the silver powder does not melt at 220° C. unless it is combined with an organic material. In other words, even if the thickness of the silver powder is as small as 100nm or less, low-temperature sintering is possible by internal reaction heat based on appropriate combination with organic materials.

The results of Examples 2 to 7 in addition to the results of Example 1 show that sintering is considered to occur at a low temperature due to the heat of curing reaction of the epoxy resin and the reactive glycidyl ether, and the reduction of the distance between the silver powder particles due to the silsesquioxane polymer resin.

FIG. 4 shows the surface image (DST) after the adhesion strength test according to the type of metal plated on the DBC substrate, and the SEM image and porosity of the sintered composition.

As can be seen from FIG. 4 showing the SEM image of the adhesive layer according to the chip bonding composition, the chip bonding composition has been sufficiently sintered.

In addition, the adhesive strength when measuring chip shear strength was so strong that the degree of chip breakage was represented by adhesive strength.

It can be seen that, when the chip size is 5 mm, the original adhesive strength can be maintained without cracking or peeling even after the thermal cycle (TC) test when the pressure is 15 GPa or less at room temperature and the pressure is 7 GPa or less at 200° C.

TABLE 3

| | | Compar- | Compar- | Compar- | Compar- | Compar- | Compar- | Compar- |
|---|---|---|---|---|---|---|---|---|
| | | ative | ative | ative | ative | ative | ative | ative |
| | | Exam- | Exam- | Exam- | Exam- | Exam- | Exam- | Exam- |
| Component | | ple 1 | ple 2 | ple 3 | ple 4 | ple 5 | ple 6 | ple 7 |
| Epoxy | Triglycidyl ρ- | 1.7 | 1.7 | 3.0 | | | | 6.3 |
| resin | aminophenol (TGPAP) | | | | | | | |
| | Tetraglycidyl | | | | 3.1 | | 3.0 | |
| | diaminodiphenylmethane | | | | | | | |
| | (TGDDM) | | | | | | | |
| | Diglycidyl of aniline | | | | | | | |
| | Diglycidyl of toluidine | | | | | | | |
| | Bisphenol A epoxy | 1.9 | 1.9 | 3.0 | 3.1 | 6.1 | 3.0 | |
| | Urethane modified epoxy | | | | | | | |
| Curing | Methyltetrahydrophthalic | 4.5 | 4.5 | 6.1 | 6.3 | 6.1 | 6.3 | 6.3 |
| agent | anhydride (MeTHPA) | | | | | | | |
| | Methylhexahydrophthalic | | | | | | | |
| | anhydride (MeHHPA) | | | | | | | |
| | Nadic methyl | | | | | | | |
| | anhydride (NMA) | | | | | | | |
| Catalyst | 2E4MZ | 0.06 | 0.06 | 0.06 | 0.06 | 0.06 | 0.06 | 0.06 |
| Silver powder | | 100 | 100 | 100 | 100 | 100 | 100 | 100 |
| PSQ | PMSQ | 4.2 | | | 0.5 | 1.1 | 2.3 | 2.3 |
| resin | | | | | | | | |
| Polybutadiene dispersant | | | | | | | | |
| PPGDE | Polypropylene glycol | | | | | | | |
| diluent | diglycidyl ether | | | | | | | |
| | BGE (Butyl | | 3.0 | | 3.0 | 0.2 | 0.1 | 1.3 |
| | Glycidyl Ether) | | | | | | | |

TABLE 4

| | | Compar- | Compar- | Compar- | Compar- | Compar- | Compar- | Compar- |
|---|---|---|---|---|---|---|---|---|
| | | ative | ative | ative | ative | ative | ative | ative |
| | | Exam- | Exam- | Exam- | Exam- | Exam- | Exam- | Exam- |
| Property | Unit | ple 1 | ple 2 | ple 3 | ple 4 | ple 5 | ple 6 | ple 7 |
| Specific | ×10⁻⁶ Qcm | 9.78 | 12.32 | 10.51 | 19.87 | 9.64 | 14.21 | 13.2 |
| resistance | | | | | | | | |
| Thermal | W/mK | 33 | 28 | 29 | 12 | 22 | 27 | 31 |
| conductivity | | | | | | | | |
| Chip | kgf/mm² | 3.8 | 2.5 | 2.9 | 6.5 | 4.2 | 4.8 | 5.6 |
| adhesive | | | | | | | | |
| strength | | | | | | | | |
| Storage | GPa | 22.2 | 19.2 | 25.9 | 16.8 | 17.2 | 13.4 | 15.8 |
| modulus | | | | | | | | |
| at 25° C. | | | | | | | | |
| Storage | GPa | 9.2 | 8.5 | 7.8 | 7.8 | 6.2 | 5.8 | 6.1 |
| modulus | | | | | | | | |
| at 200° C. | | | | | | | | |
| Thermal | Pass | Fail | Fail | Fail | Fail | Fail | Fail | Fail |
| cycle test | | | | | | | | |
| (JEDECG | | | | | | | | |
| grade) | | | | | | | | |

In Table 4, Comparative Example 1 has almost the same composition as Example 1, except that the PMSQ content is increased without addition of BGE diluent. As can be seen from Table 4, Comparative Example 1 exhibits a much higher storage modulus and a lower thermal conductivity than that of Example 1. These results indicate that the silver powder was not sufficiently sintered.

Although not shown in the table, the workability of patterning of Comparative Example 1 was not good.

Comparative Example 2 is a sample containing no PSQ resin, and Comparative Example 3 is a sample containing neither PSQ resin nor diluent. Comparative Example 4 is a sample that has a PSQ resin content outside of the range defined above, Comparative Examples 5 and 7 are samples containing a single epoxy resin, and Comparative Example 6 is a sample that has a PSQ resin content outside of the range defined above.

It can be seen that, when a single epoxy resin is used, or when a PMSQ resin or a reactive glycidyl ether diluent is used alone, sufficient sintering is not achieved, resulting in low thermal conductivity and relatively low adhesion.

TABLE 5

| | | Compar- | Compar- | Compar- |
|---|---|---|---|---|
| | | ative | ative | ative |
| | | Exam- | Exam- | Exam- |
| Component | | ple 8 | ple 9 | ple 10 |
| Epoxy | Triglycidyl ρ- | 6.0 | 1.7 | 1.7 |
| resin | aminophenol (TGPAP) | | | |
| | Tetraglycidyl | | | |
| | Diaminodiphenylmethane | | | |
| | (TGDDM) | | | |
| | Diglycidyl of aniline | | | |
| | Diglycidyl of toluidine | | | |
| | Bisphenol A epoxy | 2.4 | 2.0 | 2.0 |
| | Urethane modified epoxy | | | |
| Curing | Methyltetrahydrophthalic | 8.3 | 4.7 | 4.6 |
| agent | anhydride (MeTHPA) | | | |
| | Methylhexahydrophthalic | | | |
| | anhydride (MeHHPA) | | | |
| | Nadic methyl anhydride | | | |
| | (NMA) | | | |
| Catalyst | 2E4MZ | 0.06 | 0.06 | 0.06 |
| Silver powder | | 100 | 100 | 100 |
| PSQ | PMSQ | 2.4 | 7.0 | 2.3 |
| resin | | | | |
| Polybutadiene dispersant | | | | |
| PPGDE | Polypropylene glycol | | | 4.0 |
| diluent | diglycidyl ether | | | |
| | BGE (Butyl Glycidyl | | 0.9 | |
| | Ether) | | | |

TABLE 6

| | | Comparative | Comparative | Comparative |
|---|---|---|---|---|
| Property | Unit | Example 8 | Example 9 | Example 10 |
| Specific | ×10⁻⁶ Qcm | 24.55 | 8.52 | 17.90 |
| resistance | | | | |
| Thermal | W/mK | 7.8 | 62 | 18 |
| conductivity | | | | |
| Chip | kgf/mm² | 1.2 | 1.7 | 2.5 |
| adhesive | | | | |
| strength | | | | |
| Storage | GPa | 13.9 | 10.6 | 12.2 |
| modulus at | | | | |
| 25° C. | | | | |
| Storage | GPa | 4.1 | 3.5 | 4.3 |
| modulus at | | | | |
| 200° C. | | | | |
| Thermal | Pass | Fail | Fail | Fail |
| cycle test | | | | |
| (JEDECG | | | | |
| grade) | | | | |

As can be seen from Table 5, Comparative Example 8 is a sample that has a total epoxy resin content outside of the range defined above, Comparative Example 9is a sample that that has a PSQ resin content outside of the range defined above, and Comparative Example 10 is a sample that that has a diluent content outside of the range defined above.

Comparative Example 8 had a high binder (epoxy resin) content compared to the silver powder, causing formation of an excessively cured matrix. Accordingly, the binder acts to impede necking of the silver powder and lower the sintering characteristics, resulting in low thermal conductivity and adhesive strength.

Comparative Example 9 had a low modulus value but exhibits poor chip bonding workability due to poor dispersibility and high viscosity. In addition, it can be seen that Comparative Example 9 exhibits poor wettability between the interface between the chip and the composition (bonding layer) and the interface between the substrate and the composition (bonding layer), causing a decrease in adhesive strength and a failure in reliability.

Comparative Example 10 has a relatively low modulus value but requires heat treatment conditions at a high temperature due to the delayed curing rate and decreased heat generation of the curing reaction. It can be seen that adhesion was insufficient and thermal conductivity was low under low temperature conditions.

As such, all chip bonding compositions of Comparative Examples 1 to 10 exhibit high modulus or significantly low thermal conductivity and adhesion. This causes cracks and peeling during thermal cycle (TC) testing of the power semiconductor package, resulting in poor reliability.

The present disclosure is supported by the following national research and development projects.
[Assignment number] 1425151246
[Assignment number] S3025961
[Ministry Name] Ministry of SMEs and Startups
[Project management (professional) institute name] the Korea Technology and information Promotion Agency
[Research Project Name] Collaborative technology development project with leading research institutes to support small and medium-sized businesses (R&D)
[Research project name] Development of low-modulus, high-heat dissipation bonding material for power semiconductor packages and modules for die bonding with medium and large sizes of 5×5 mm² or larger.
[Contribution rate] 1/1
[Name of project organization] Korea Institute of Electronic Technology
[Research period] 2020.11.01 ˜ 2021.10.31

Although the preferred embodiments of the present disclosure have been disclosed with reference to illustrative drawings, it would be obvious that the present disclosure is not limited to the embodiments and drawings disclosed in this specification and that those skilled in the art will appreciate that various modifications, additions and substitutions are possible, without departing from the scope and spirit of the invention as disclosed in the accompanying claims. In addition, it would be obvious that although the effects obtained by the configurations of the present disclosure are not explicitly described with reference to the embodiments of the present disclosure, effects that can be predicted by the configurations should also be recognized.

1. A chip bonding composition comprising:
a silver powder;
an epoxy resin;
a curing agent;
a catalyst;
a glycidyl ether-based diluent; and
a polysilsesquioxane (PSQ) resin.

2. The chip bonding composition according to claim 1, wherein the epoxy resin comprises a glycidyl amine-based epoxy resin and a bisphenol A epoxy resin.

3. The chip bonding composition according to claim 1, wherein the chip bonding composition comprises 1to 7 parts by weight of the epoxy resin, 0.01 to 5 parts by weight of the catalyst, 0.2 to 3 parts by weight of the glycidyl ether-based diluent, and 1 to 6 parts by weight of the polysilsesquioxane (PSQ) resin, based on 100 parts by weight of the silver powder, and a mixing ratio of the epoxy resin to the curing agent is a weight ratio of 1:1 to 1:2.

4. The chip bonding composition according to claim 1, wherein the curing agent comprises an acid anhydride-based curing agent.

5. The chip bonding composition according to claim 1, wherein the catalyst comprises an imidazole-based catalyst.

6. The chip bonding composition according to claim 1, wherein the glycidyl ether-based diluent comprises at least one of lauryl alcohol glycidyl ether (LGE), butyl glycidyl ether (BGE), 2-ethylhexyl glycidyl ether, allyl glycidyl ether (AGE), polypropylene glycol diglycidyl ether, 1,4-butanediol diglycidylether, neopentyl glycol diglycidyl ether, or 1,6-hexanediol diglycidyl ether.

7. The chip bonding composition according to claim 1, wherein the polysilsesquioxane resin comprises at least one of polypropylene silsesquioxane, polyphenyl silsesquioxane, or polymethylene silsesquioxane.

8. The chip bonding composition according to claim 1, further comprising at least one of a butadiene-based dispersant, a phosphoric acid-based dispersant, or an ester-based dispersant.

9. The chip bonding composition according to claim 1, wherein the chip bonding composition has a chip bonding strength of 4.0 to 10.0 kgf/mm²,
wherein the chip bonding strength is measured at room temperature using a die shear tester after dispensing the chip bonding composition on a substrate, placing a 5 mm×5 mm chip on the substrate, and heat-treating the chip at 240° C.

10. The chip bonding composition according to claim 1, wherein the chip bonding composition has a storage modulus of 3 to 7 GPa,
wherein the storage modulus is measured at 200° C. at a frequency of 1 Hz using a dynamic mechanical analyzer (DMA).
